(19) United States
(12) Patent Application Publication
(10) Pub. No.: US 2016/0005890 A1
(43) Pub. Date: Jan. 7, 2016

(54) COMPOSITION FOR FORMING ELECTRODE OF SOLAR CELL AND ELECTRODE FORMED THEREFROM

(71) Applicant: CHEIL INDUSTRIES INC., Gumi-si Gyeongsangbuk-do (KR)

(72) Inventors: Dong Suk KIM, Uiwang-si, Gyeonggi-do (KR); Min Jae KIM, Uiwang-si, Gyeonggi-do (KR); Eun Kyung KIM, Uiwang-si, Gyeonggi-do (KR); Seok Hyun JUNG, Uiwang-si, Gyeonggi-do (KR); Young Wook CHOI, Uiwang-si, Gyeonggi-do (KR)

(21) Appl. No.: 14/769,912

(22) PCT Filed: Feb. 4, 2014
(86) PCT No.: PCT/KR2014/000941

§ 371 Date: Aug. 24, 2015

(30) Foreign Application Priority Data
Jun. 5, 2013 (KR) 10-2013-0065010

(51) Int. Cl. H01L 31/0224; H01L 31/18; C09D 5/24

(52) U.S. Cl. CPC H01L 31/022425; C09D 5/24; H01L 31/18

(57) ABSTRACT

Disclosed herein is a composition for solar cell electrodes. The composition includes a silver powder; a bismuth oxide-tellurium oxide-tungsten oxide-based glass frit; and an organic vehicle, wherein the glass frit includes about 40% by weight (wt %) to about 60 wt % of bismuth oxide as a first metal oxide; about 0.25 wt % to about 15 wt % of tellurium oxide as a second metal oxide; about 10 wt % to about 20 wt % of tungsten oxide as a third metal oxide; and about 15 wt % to about 25 wt % of a fourth metal oxide different from the first, second, and third metal oxides. Solar cell electrodes formed of the composition have excellent adhesive strength with respect to a ribbon while minimizing serial resistance (Rs), thereby providing high conversion efficiency.

### TECHNICAL FIELD

The present invention relates to a composition for solar cell electrodes and electrodes fabricated using the same.

### BACKGROUND ART

Solar cells generate electric energy using the photovoltaic effect of a p-n junction which converts photons of sunlight into electricity. In the solar cell, front and rear electrodes are formed on upper and lower surfaces of a semiconductor wafer or substrate with the p-n junction, respectively. Then, the photovoltaic effect of the p-n junction is induced by sunlight entering the semiconductor wafer and electrons generated by the photovoltaic effect of the p-n junction provide electric current to the outside through the electrodes. The electrodes of the solar cell are formed on the wafer by applying, patterning, and baking a composition for electrodes.

Continuous reduction in emitter thickness for improvement of solar cell efficiency can cause shunting which can deteriorate solar cell performance. In addition, a solar cell has been gradually increased in area to achieve high efficiency. In this case, however, there can be a problem of efficiency deterioration due to increase in contact resistance of the solar cell.

Solar cells are connected to each other by a ribbon to constitute a solar cell battery. In this case, low adhesion between electrodes and the ribbon can cause large serial resistance and deterioration in conversion efficiency. Moreover, electrodes fabricated by using a composition for solar cell electrodes including conventional leaded glass frits exhibit insufficient adhesive strength with respect to the ribbon. In this point of view, the inventor developed a solar cell capable of overcoming such problems.

### DISCLOSURE

### Technical Problem

It is one aspect of the present invention to provide a composition for solar cell electrodes, which has excellent adhesive strength with respect to a ribbon.

It is another aspect of the present invention to provide a composition for solar cell electrodes, which has minimizes serial resistance (Rs).

It is another aspect of the present invention to provide a composition for solar cell electrodes, which has excellent conversion efficiency.

The above and other aspect and features of the present invention can be accomplished by the present invention described hereinafter.

### TECHNICAL SOLUTION

In accordance with one aspect of the invention, a composition for solar cell electrodes include: a silver powder; a bismuth oxide-tellurium oxide-tungsten oxide-based glass frit; and an organic vehicle, wherein the glass frit includes about 40% by weight (wt %) to about 60 wt % of bismuth oxide as a first metal oxide; about 0.25 wt % to about 15 wt % of tellurium oxide as a second metal oxide; about 10 wt % to about 20 wt % of tungsten oxide as a third metal oxide; and about 15 wt % to about 25 wt % of a fourth metal oxide different from the first, second, and third metal oxides.

The fourth metal oxide may include at least one metal oxide of lithium oxide, vanadium oxide, silicon oxide, bismuth oxide, zinc oxide, magnesium oxide, boron oxide, and aluminum oxide.

The composition may include about 60 wt % to about 95 wt % of the silver powder; about 0.5 wt % to about 20 wt % of the bismuth oxide-tellurium oxide-tungsten oxide-based glass frit; and about 1 wt % to about 30 wt % of the organic vehicle.

The glass frit may have an average particle diameter (D50) of about 0.1 μm to about 5 μm.

The composition may further include at least one additive of dispersants, thixotropic agents, plasticizers, viscosity stabilizers, anti-foaming agents, pigments, UV stabilizers, antioxidants, and coupling agents.

In accordance with another aspect of the present invention, there is provided a solar cell electrode formed using the composition for solar cell electrodes.

### ADVANTAGEOUS EFFECTS

A solar cell electrode formed of the composition for solar cell electrodes according to embodiments of the present invention, has excellent adhesive strength with respect to a ribbon and minimizes serial resistance (Rs), thereby providing excellent conversion efficiency.

### DESCRIPTION OF DRAWINGS

FIG. 1 is a schematic view of a solar cell manufactured using a composition in accordance with one embodiment of the present invention.

### BEST MODE

Composition for solar cell electrodes

A composition for solar cell electrodes according to the invention includes a silver powder; a bismuth oxide-tellurium oxide-tungsten oxide-based glass frit, and an organic vehicle. The composition exhibits excellent adhesive strength with respect to a ribbon connecting solar cells to each other and minimizes serial resistance (Rs), thereby providing excellent fill factor and conversion efficiency.

Now, the present invention will be described in more detail.

(A) Silver powder

The composition for solar cell electrodes according to the invention includes a silver powder, which is a conductive powder, as a first metal powder. The particle size of the silver powder may be on nanometer or micrometer scale.

For example, the silver powder may have a particle size of dozens to several hundred nanometers, or several to dozens of micrometers. Alternatively, the silver powder may be a mixture of two or more types of silver powders having different particle sizes.

The silver powder may have a spherical, flake or amorphous shape.

The silver powder preferably has an average particle diameter (D50) of about 0.1 μm to about 10 μm, more preferably about 0.5 μm to about 5 μm. The average particle diameter may be measured using, for example, a Model 1064D (CILAS Co., Ltd.) after dispersing the conductive powder in isopropyl alcohol (IPA) at 25° C. for 3 minutes via ultrasonication. Within this range of average particle diameter, the composition can provide low contact resistance and low line resistance.

The silver powder may be present in an amount of about 60 wt % to about 95 wt % based on the total weight of the composition. Within this range, the conductive powder can prevent deterioration in conversion efficiency due to increase in resistance. Advantageously, the conductive powder is present in an amount of about 70 wt % to about 90 wt %.

(B) Bismuth oxide-tellurium oxide-tungsten oxide-based glass frit

The glass frit serves to enhance adhesion between the conductive powder and the wafer or the substrate and to form silver crystal grains in an emitter region by etching an anti-reflection layer and melting the silver powder so as to reduce contact resistance during a baking process of the electrode paste. Further, during the baking process, the glass frit is softened and decreases the baking temperature.

When the area of the solar cell is increased in order to improve solar cell efficiency, there can be a problem of increase in contact resistance of the solar cell. Thus, it is necessary to minimize serial resistance (Rs) and influence on the p-n junction.

In addition, as the baking temperatures varies within a broad range with increasing use of various wafers having different sheet resistances, the glass frit should secure sufficient thermal stability to withstand a wide range of baking temperatures.

Solar cells are connected to each other by a ribbon to constitute a solar cell battery. In this case, low adhesive strength between solar cell electrodes and the ribbon can cause detachment of the cells or deterioration in reliability.

In this invention, in order to ensure that the solar cell has desirable electrical and physical properties such as conversion efficiency and adhesive strength, a bismuth oxide-tellurium oxide-tungsten oxide-based (Bi₂O₃—TeO₂—WO₃) lead-free glass frit is used.

The bismuth oxide-tellurium oxide-tungsten oxide-based lead-free glass frit essentially includes bismuth oxide, tellurium oxide, and tungsten oxide as first, second, and third metal oxides, and may further include a fourth metal oxide different from the first, second, and third metal oxides.

In one embodiment, the glass frit may include about 40 wt % to about 60 wt % of bismuth oxide as the first metal oxide; about 0.25 wt % to about 15 wt % of tellurium oxide as the second metal oxide; about 10 wt % to about 20 wt % of tungsten oxide as the third metal oxide; and about 15 wt % to about 25 wt % of the fourth metal oxide. Within this range, the glass frit can secure both excellent adhesive strength and excellent conversion efficiency.

The fourth metal oxide may include at least one of lithium oxide, vanadium oxide, silicon oxide, bismuth oxide, zinc oxide, magnesium oxide, boron oxide, and aluminum oxide.

The glass frit may be prepared from such metal oxides by any typical method. For example, the metal oxides may be mixed in a predetermined ratio. Mixing may be carried out using a ball mill or a planetary mill. The mixed composition is melted at about 900° C. to about 1300° C., followed by quenching to 25° C. The obtained resultant is subjected to pulverization under a disk mill, a planetary mill, or the like, thereby providing a glass frit.

The glass frit may have an average particle diameter D50 of about 0.1 μm to about 10 μm, and may be present in an amount of about 0.5 wt % to about 20 wt % based on the total amount of the composition. The glass frit may have a spherical or amorphous shape.

(C) Organic vehicle

The organic vehicle imparts suitable viscosity and rheological characteristics for printing to the paste composition through mechanical mixing with the inorganic component of the composition for solar cell electrodes.

The organic vehicle may be any typical organic vehicle used for the composition for solar cell electrodes, and may include a binder resin, a solvent, and the like.

The binder resin may include acrylate resins, cellulose resins and the like. Ethyl cellulose is generally used as the binder resin. In addition, the binder resin may include ethyl hydroxyethyl cellulose, nitrocellulose, blends of ethyl cellulose and phenol resins, alkyd resins, phenol resins, acrylic ester resins, xylenic resins, polybutene resins, polyester resins, urea resins, melamine resins, vinyl acetate resins, wood rosin, polymethacrylates of alcohols, and the like.

Examples of the solvent may include hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, y-butyrolactone, ethyl lactate, and the like. These solvents may be used alone or in combinations thereof

The organic vehicle may be present in an amount of about 1 wt % to about 30 wt % based on the total weight of the composition. Within this range, the organic vehicle can provide sufficient adhesive strength and excellent printability to the composition.

(D) Additives

The composition may further include typical additives, as needed, to enhance flow properties, process properties, and stability.

The additives may include dispersants, thixotropic agents, plasticizers, viscosity stabilizers, anti-foaming agents, pigments, UV stabilizers, antioxidants, coupling agents, and the like, without being limited thereto. These additives may be used alone or as mixtures thereof These additives may be present in an amount of about 0.1 wt % to about 5 wt % in the composition, but this amount may be changed as needed.

Solar cell electrode and solar cell including the same

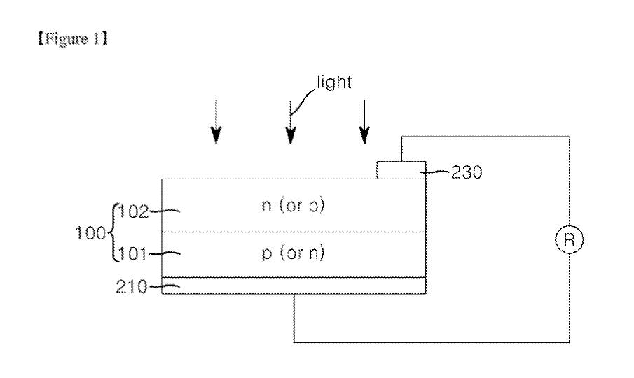

Other aspects of the present invention relate to an electrode formed of the composition for solar cell electrodes and a solar cell including the same. FIG. 1 shows a solar cell in accordance with one embodiment of the present invention.

Referring to FIG. 1, a rear electrode 210 and a front electrode 230 may be formed by printing and baking the composition on a substrate or wafer 100 that includes a p-layer 101 and an n-layer 102, which will serve as an emitter. For example, a preliminary process for preparing the rear electrode 210 is performed by printing the composition on the rear surface of the wafer 100 and drying the printed composition at about 200° C. to about 400° C. for about 10 seconds to about 60 seconds. Further, a preliminary process for preparing the front electrode 230 may be performed by printing the paste on the front surface of the wafer and drying the printed composition. Then, the front electrode 230 and the rear electrode 210 may be formed by baking the wafer at about 400° C. to about 950° C., preferably at about 850° C. to about 950° C., for about 30 seconds to about 50 seconds.

### MODE FOR INVENTION

Hereinafter, the present invention will be described in further detail with reference to exemplary embodiments. However, it should be understood that the description proposed herein is just a preferable example for the purpose of illustrations only, not intended to limit the scope of the invention.

### EXAMPLES

### Example 1

Bismuth oxide, tellurium oxide, and tungsten oxide, as the first, second, and third metal oxides, as well as lithium oxide and vanadium oxide, as the fourth metal oxide were mixed according to the composition listed in Table 1 and subjected to melting and sintering at 900° C. to 1400° C., thereby preparing bismuth oxide-tellurium oxide-tungsten oxide-based glass frits having an average particle diameter (D50) of 2.0 μm.

As an organic binder, 0.8 wt % of ethylcellulose (STD4, Dow Chemical Company) was sufficiently dissolved in 8.5 wt % of butyl carbitol at 60° C., and 86.3 wt % of spherical silver powders (AG-4-8, Dowa Hightech Co. Ltd.) having an average particle diameter of 2.0 μm, 3.5 wt % of the prepared bismuth oxide-tellurium oxide-tungsten oxide-based glass fits, 0.2 wt % of a dispersant BYK102 (BYK-Chemie, BYK Co., Ltd.) and 0.5 wt % of a thixotropic agent Thixatrol ST (Elementis Co., Ltd.) were added to the binder solution, followed by mixing and kneading in a 3-roll kneader, thereby preparing a composition for solar cell electrodes.

The prepared composition was deposited over a front surface of a crystalline mono-wafer by screen printing in a predetermined pattern, followed by drying in an IR drying furnace. Then, the composition for electrodes containing aluminum was printed on a rear side of the wafer and dried in the same manner.

Cells formed according to this procedure were subjected by baking at 940° C. for 40 seconds in a belt-type baking furnace, and evaluated as to conversion efficiency (%) and serial resistance Rs (Ω) using a solar cell efficiency tester CT-801 (Pasan Co., Ltd.). Then, flux was applied to the electrodes of the cells and bonded to a ribbon at 300° C. to 400° C. using a soldering iron (Hakko Co., Ltd.). Then, the resultant was evaluated as to adhesive strength (N/mm) at a peeling angle of 180° and a stretching rate of 50 mm/min using a tensioner (Tinius Olsen Co., Ltd.). The measured conversion efficiency, serial resistance, and adhesive strength (N/m) are shown in Table 1.

### Example 2 to 5 and Comparative Example 1 to 6

Compositions for solar cell electrodes were prepared and evaluated as to physical properties in the same manner as in Example 1 except that the glass frits were prepared in compositions as listed in Table 1. Results are shown in Table 1.

TABLE 1

| | | | | | | | | Adhesive | | Conversion |
|---|---|---|---|---|---|---|---|---|---|---|
| | Composition of glass frit (unit: wt %) | | | | | | | Strength | Rs | efficiency |
| | PbO | Bi₂O₃ | TeO₂ | WO₃ | B₂O₃ | Li₂O | V₂O₅ | (N/mm) | (Ω) | (%) |
| Example 1 | — | 58 | 5 | 20 | — | 1 | 16 | 2.98 | 0.0057 | 17.58 |
| Example 2 | — | 58 | 15 | 20 | — | 1 | 6 | 3.85 | 0.0058 | 17.51 |
| Example 3 | — | 60 | 15 | 15 | — | 1 | 9 | 4.12 | 0.0056 | 17.65 |
| Example 4 | — | 58 | 12 | 18 | — | 1 | 11 | 3.43 | 0.0054 | 17.64 |
| Example 5 | — | 58 | 17 | 12 | — | 1 | 12 | 3.55 | 0.0058 | 17.52 |
| Comparative | 40 | — | 30 | 30 | — | — | — | 2.31 | 0.0058 | 17.55 |
| Example 1 | | | | | | | | | | |
| Comparative | — | 35 | 15 | 15 | 10 | 1 | 24 | 1.78 | 0.0061 | 17.48 |
| Example 2 | | | | | | | | | | |
| Comparative | — | 70 | 12 | 14 | — | 1 | 3 | 2.69 | 0.0067 | 17.41 |
| Example 3 | | | | | | | | | | |
| Comparative | — | 55 | 20 | 10 | — | 1 | 14 | 2.23 | 0.0058 | 17.49 |
| Example 4 | | | | | | | | | | |
| Comparative | — | 60 | 15 | 8 | — | 1 | 16 | 1.2 | 0.0055 | 17.59 |
| Example 5 | | | | | | | | | | |
| Comparative | — | 60 | 15 | 22 | — | 1 | 2 | 1.89 | 0.0054 | 17.6 |
| Example 6 | | | | | | | | | | |

As shown in Table 1, the solar cell electrodes fabricated using the compositions prepared in Examples 1 to 5 exhibit considerably high adhesive strength with respect to the ribbons as well as low serial resistance and excellent conversion efficiency, as compared with that of Comparative Example 1 wherein a leaded glass frit was used, and those of Comparative Examples 2 to 6 wherein the compositions of the glass frits did not satisfy the present invention.

It should be understood that various modifications, changes, alterations, and equivalent embodiments can be made by those skilled in the art without departing from the spirit and scope of the invention.

1. A composition for solar cell electrodes, comprising:
an organic vehicle;
a silver powder; and
a bismuth oxide-tellurium oxide-tungsten oxide glass frit the bismuth oxide-tellurium oxide-tungsten oxide glass fit including about 40 wt % to about 60 wt % of bismuth oxide as a first metal oxide; about 0.25 wt % to about 15 wt % of tellurium oxide as a second metal oxide; about 10 wt % to about 20 wt % of tungsten oxide as a third metal oxide;
and about 15 wt % to about 25 wt % of a fourth metal oxide different from the first, second, and third metal oxides.

2. The composition for solar cell electrodes according to claim 1, wherein the fourth metal oxide includes one or more of lithium oxide, vanadium oxide, silicon oxide, zinc oxide, magnesium oxide, boron oxide, or aluminum oxide.

3. The composition for solar cell electrodes according to claim 1, wherein the composition includes: about 60 wt % to about 95 wt % of the silver powder; about 0.5 wt % to about 20 wt % of the bismuth oxide-tellurium oxide-tungsten oxide glass fit; and about 1 wt % to about 30 wt % of the organic vehicle.

4. The composition for solar cell electrodes according to claim 1, wherein the bismuth oxide-tellurium oxide-tungsten oxide glass frit has an average particle diameter (D50) of about 0.1 μm to about 5 μm.

5. The composition for solar cell electrodes according to claim 1, further comprising one or more of a dispersant, a thixotropic agent, a plasticizer, a viscosity stabilizer, an anti-foaming agent, a pigment, a UV stabilizer, an antioxidant, or a coupling agent.

6. A solar cell electrode prepared from the composition for solar cell electrodes according to claim 1.

7. A method of manufacturing a solar cell, the method comprising:
printing the composition according to claim 1 in a predetermined pattern over a front surface of a wafer; and
firing the printed composition pattern to form at least electrode.

8. A solar cell manufactured according to the method of claim 7.
